(19) United States
(12) Patent Application Publication
(10) Pub. No.: US 2008/0261390 A1
(43) Pub. Date: Oct. 23, 2008

(54) METHOD FOR FORMING BUMPS ON UNDER BUMP METALLURGY

(75) Inventors: Chien Fan CHEN, Kaohsiung City (TW); Min Lung HUANG, Kaohsiung (TW)

Correspondence Address: LOWE HAUPTMAN HAM & BERNER, LLP, 1700 DIAGONAL ROAD, SUITE 300, ALEXANDRIA, VA, 22314, US

(73) Assignee: ADVANCED SEMICONDUCTOR ENGINEERING INC., Pingtung City (TW)

(21) Appl. No.: 12/104,712

(22) Filed: Apr. 17, 2008

(30) Foreign Application Priority Data
Apr. 17, 2007 (TW) 096113466

(51) Int. Cl. H01L 21/44

(52) U.S. Cl. 438/613; 257/E21.476

(57) ABSTRACT

A method for forming metal bumps is provided. A bonding pad is first formed on the active surface of a chip and then a passivation layer is formed on the active surface of the chip and exposes the bonding pad. An under bump metallurgy is formed on the active surface of the chip to overlay the bonding pad. A layer of patterned photoresist is formed on the under bump metallurgy and exposes the portion of the under bump metallurgy on the bonding pad. A layer of copper is plated on the exposed portion of the under bump metallurgy and then a layer of solder is printed on the copper layer. Afterward the solder is reflowed to form a spherical metal bump. Finally, the photoresist layer is removed and the exposed portion of the under bump metallurgy is etched out.

### CROSS REFERENCE TO RELATED APPLICATION

This application claims the priority benefit of Taiwan Patent Application Serial Number 096113466 filed Apr. 17, 2007, the full disclosure of which is incorporated herein by reference.

### BACKGROUND OF THE INVENTION

1. Field of the Invention

The invention relates to a method for forming bumps and more particularly, to a method for forming bumps on under bump metallurgy by printing.

2. Description of the Related Art

It is common that a chip is electrically connected to external circuitry by wire-bonding in the art. However, more room is required to accommodate the bonding wires and the working frequency of the chip is also limited. Therefore, to solve the above problems, the flip-chip bonding technology has been developed to replace the conventional wire-bonding technology.

The so-called flip-chip bonding technology is first to form under bump metallurgy on a chip and metal bumps are then formed on the under bump metallurgy. The chip can be connected to a substrate by the metal bumps with a reflow process.

FIG. 1 illustrates the structure of the metal bump according to the conventional flip-chip bonding technology. A bonding pad 22 is formed on the active surface 27 of the chip 20. A passivation layer 23 is formed to overlay the active surface 27 of the chip 20 and expose the bonding pad 22. The passivation layer 23 acts as an isolation layer. An under bump metallurgy 24 is formed on the bonding pad 22 and a copper pillar 26 is formed on the under bump metallurgy 24. A metal bump 21 is then formed on the copper pillar 26.

The conventional method for forming the metal bump 21 on the under bump metallurgy 24 in FIG. 1 is illustrated in FIGS. 2a to 2g. First, the chip 20 is provided. The bonding pad 22 is then formed on the active surface 27 of the chip 20 (see FIG. 2a). The passivation layer 23 is formed on the active surface 27 of the chip 20 and exposes the bonding pad 22 (see FIG. 2b). Afterward the under bump metallurgy 24 is formed on the active surface 27 of the chip 20 to overlay the bonding pad 22. The under bump metallurgy 24 is made of a material selected from a group consisting of titanium, alloy of titanium and tungsten, copper, nickel, alloy of chromium and copper, alloy of nickel and vanadium, alloy of nickel and gold, aluminum and combination thereof (see FIG. 2c). A layer of patterned photoresist 32 is formed on the under bump metallurgy 24 and exposes the portion of the under bump metallurgy 24 on the bonding pad 22 (see FIG. 2d). A layer of copper 26 is plated on the exposed portion of the under bump metallurgy 24 and then a layer of solder 21′ is printed on the copper layer 26 (see FIG. 2e). After the solder 21′ is printed, the photoresist layer 32 is removed and the exposed portion of the under bump metallurgy 24 is etched out (see FIG. 2f). The flux is then applied to the solder 21′ (not shown in the figure) and the solder 21′ is reflowed to form a spherical metal bump 21 (see FIG. 2g).

According to the conventional method for forming the bump 21 on the under bump metallurgy 24, a certain portion of the molten solder 21′ will flow to the passivation layer 23 when the solder 21′ is reflowed. As a result, the metal bump 21 does not always have the shape of a perfect sphere. Moreover, when the spacing between the bumps 21 gets reduced due to the increase of the bumps 21, the portions of the solder 21′ flowing to the passivation layer 23 are likely to connect with each other and therefore cause a fatal short circuit.

Accordingly, there exists a need to provide a method for forming metal bumps to solve the above-mentioned problems.

### SUMMARY OF THE INVENTION

It is an object of the present invention to provide a method for forming metal bumps. A layer of solder is printed on the metal layer disposed on the bonding pad and the solder is reflowed to melt. The solder will form a perfectly spherical metal bump on the bonding pad after cooling down with a layer of photoresist to act as a dam.

In order to achieve the above object, the method for forming metal bumps according to the present invention is to form a bonding pad on the active surface of a chip. A passivation layer is then formed on the active surface of the chip and exposes the bonding pad. Afterward an under bump metallurgy is formed on the active surface of the chip to overlay the bonding pad. A layer of patterned photoresist is formed on the under bump metallurgy and exposes the portion of the under bump metallurgy on the bonding pad. A layer of metal is plated on the exposed portion of the under bump metallurgy and then a layer of solder is printed on the metal layer. Afterward the solder is reflowed to form a spherical metal bump. Finally, the photoresist layer is removed and the exposed portion of the under bump metallurgy is etched out.

According to the method of the present invention for forming metal bumps, the solder is applied to the metal layer by printing and the solder is reflowed to melt before the photoresist layer is removed. In this way the photoresist layer can act as a dam to prevent the molten solder from flowing to the passivation layer. This will solve the prior art problem of short circuit. Moreover, since the flow of the molten solder is limited by the photoresist layer, the solder will form a perfectly spherical metal bump after cooling down as a result of cohesion.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a cross-sectional view of a metal bump formed on a chip in the art.

FIGS. 2a to 2g illustrate the conventional method for forming metal bumps.

FIGS. 3a to 3g illustrate the method for forming metal bumps according to the present invention.

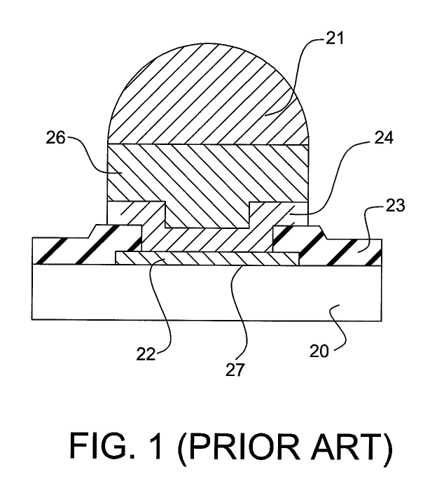

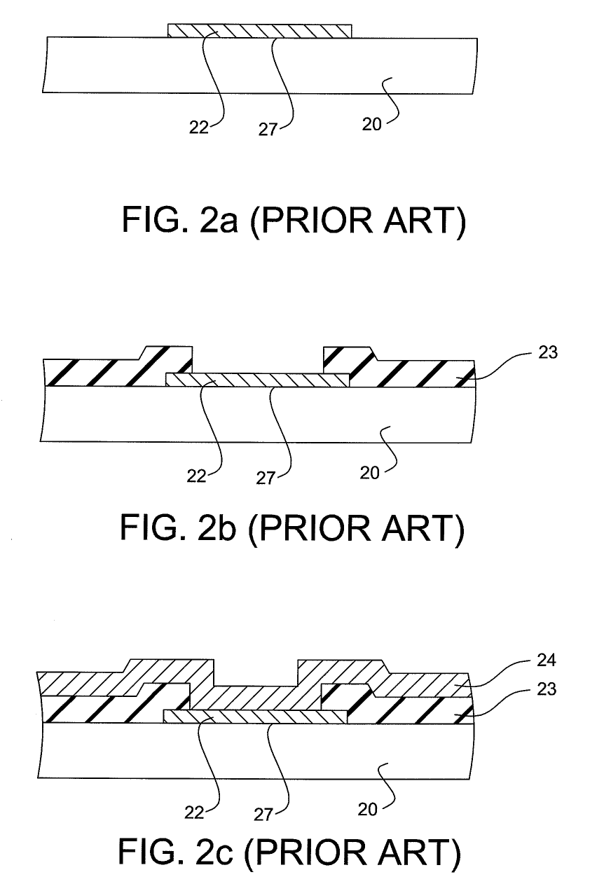

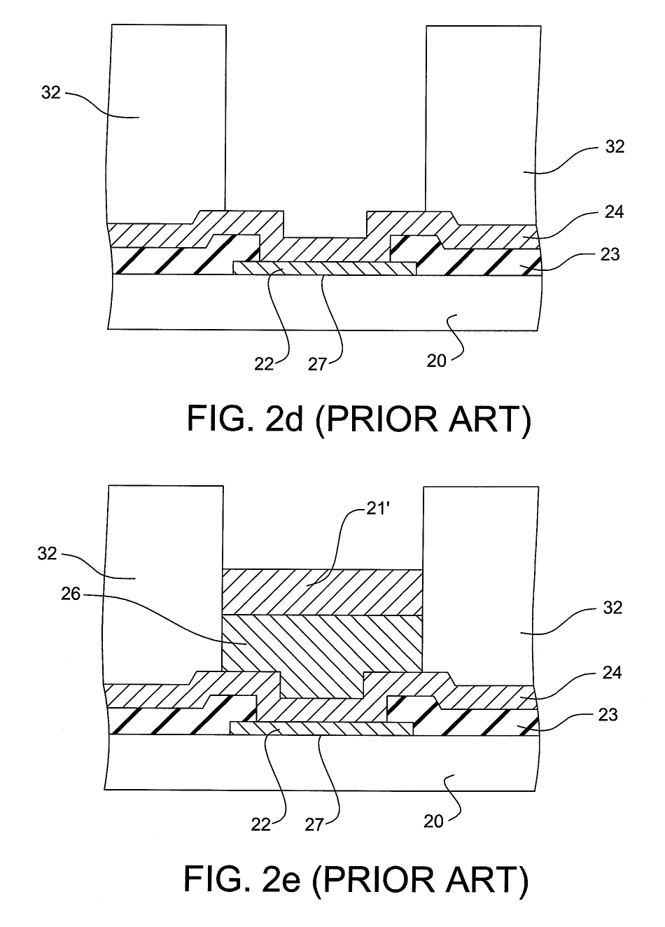

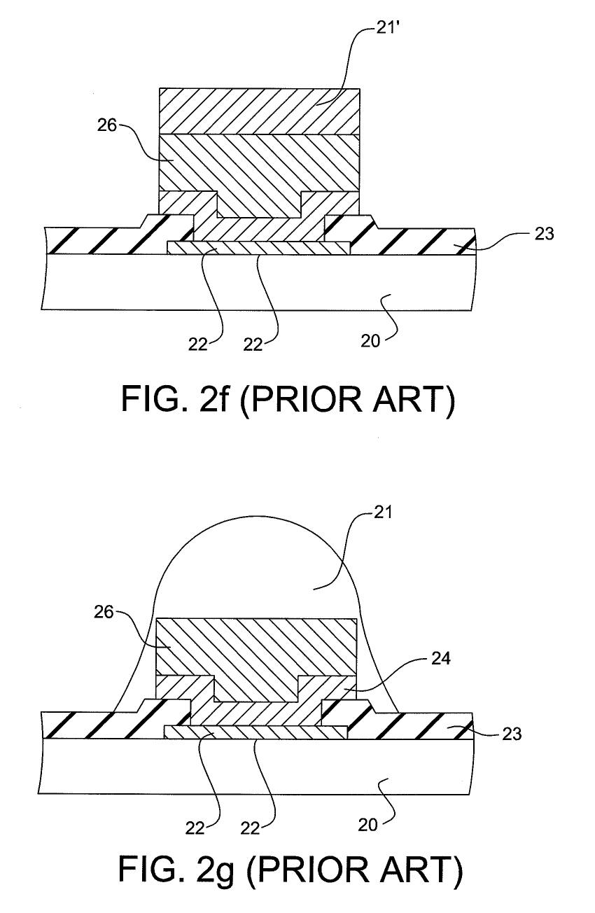

### DETAILED DESCRIPTION OF THE PREFERRED EMBODIMENT

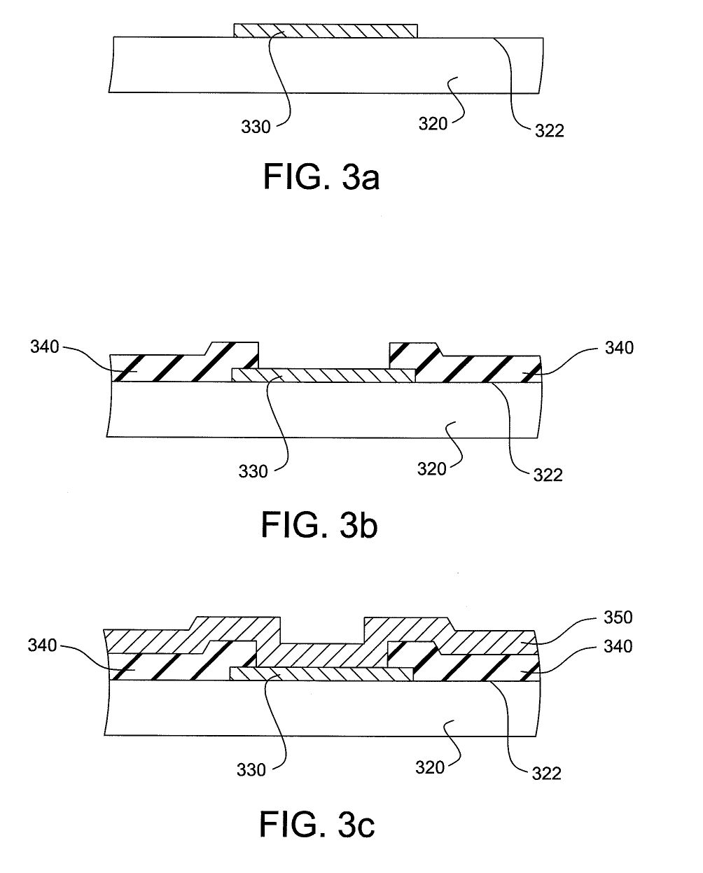

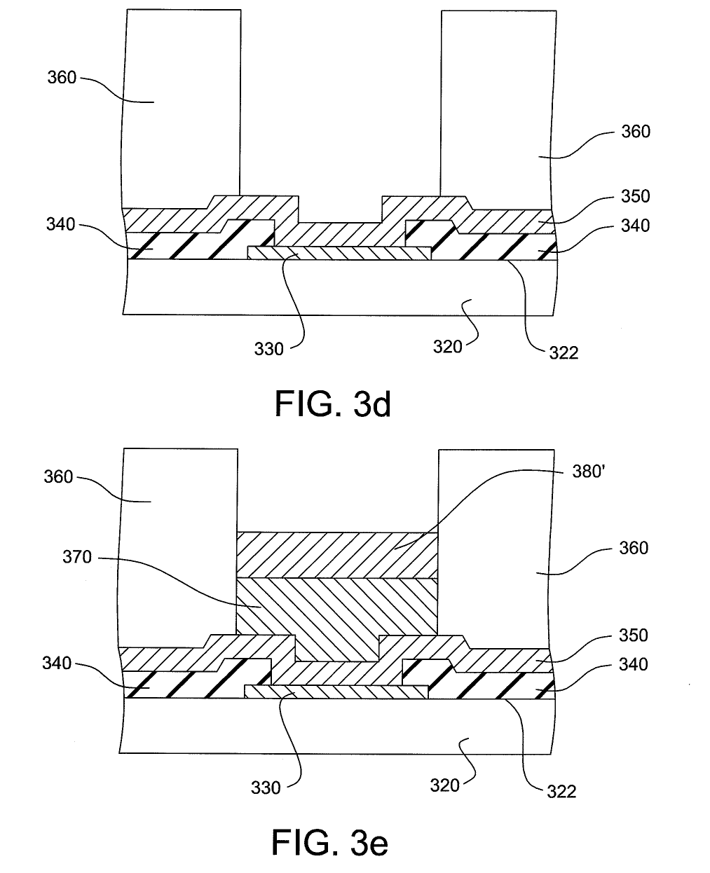

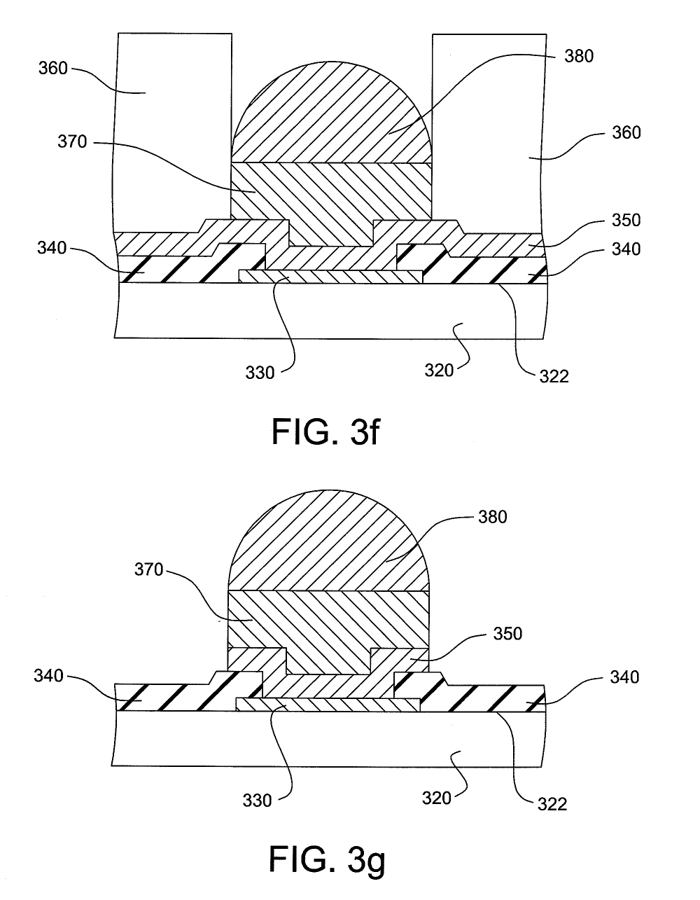

Referring to FIGS. 3a to 3g, the method for forming metal bumps according to the present invention is to form a bonding pad 330 on the active surface 322 of a chip 320 (see FIG. 3a). A passivation layer 340 is then formed on the active surface 322 of the chip 320 and exposes the bonding-pad 330 (see FIG. 3b). Afterward an under bump metallurgy 350 is formed on the active surface 322 of the chip 320 to overlay the bonding pad 330. The under bump metallurgy 350 is made of a material selected from a group consisting of titanium, alloy of titanium and tungsten, copper, nickel, alloy of chromium and copper, alloy of nickel and vanadium, alloy of nickel and gold, aluminum and combination thereof (see FIG. 3c). A layer of patterned photoresist 360 is formed on the under bump metallurgy 350 and exposes the portion of the under bump metallurgy 350 on the bonding pad 330 (see FIG. 3d). A layer of metal 370, such as copper is plated on the exposed portion of the under bump metallurgy 350 and then a layer of solder 380′ is printed on the metal layer 370 (see FIG. 3e). Afterward the solder 380′ is reflowed to form a spherical metal bump 380 (see FIG. 3f). Finally, the photoresist layer 360 is removed and the exposed portion of the under bump metallurgy 350 is etched out (see FIG. 3g).

According to the method of the present invention for forming metal bumps, the solder is applied to the metal layer by printing and the solder is reflowed to melt before the photoresist layer is removed. In this way the photoresist layer can act as a dam to prevent the molten solder from flowing to the passivation layer. This will solve the prior art problem of short circuit. Moreover, since the flow of the molten solder is limited by the photoresist layer, the solder will form a perfectly spherical metal bump after cooling down as a result of cohesion.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for forming a metal bump, comprising the steps of:
providing a chip having an active surface;
forming a bonding pad on the active surface of the chip;
forming a passivation layer on the active surface of the chip and exposing the bonding pad;
forming an under bump metallurgy on the passivation layer to overlay the bonding pad;
forming a layer of patterned photoresist on the under bump metallurgy and exposing the portion of the under bump metallurgy on the bonding pad;
forming a layer of metal on the exposed portion of the under bump metallurgy;
applying a layer of solder to the metal layer;
reflowing the solder to form a metal bump;
removing the photoresist layer after the metal bump is formed; and
removing the exposed portion of the under bump metallurgy.

2. The method as claimed in claim 1, wherein the solder is applied by printing.

3. The method as claimed in claim 1, wherein the metal layer is formed by plating.

4. The method as claimed in claim 1, wherein the metal layer is made of copper.

5. The method as claimed in claim 3, wherein the metal layer is made of copper.

6. The method as claimed in claim 1, wherein the exposed portion of the under bump metallurgy is removed by etching.
